(19) United States
(12) Patent Application Publication
(10) Pub. No.: US 2016/0154041 A1
(43) Pub. Date: Jun. 2, 2016

(54) A Synchrophasor Measurement Method Applying to P Class Phasor Measurement Unit (PMU)

(71) Applicant: NORTH CHINA ELECTRIC POWER UNIVERSITY, Beijing (CN)

(72) Inventors: Tianshu BI, Beijing (CN); Hao LIU, Beijing (CN)

(73) Assignee: NORTH CHINA ELECTRIC POWER UNIVERSITY, Beijing (CN)

(21) Appl. No.: 14/906,367

(22) PCT Filed: Apr. 18, 2014
(86) PCT No.: PCT/CN2014/075688

§ 371 Date: Jan. 20, 2016

(51) Int. Cl. G01R 29/18

(52) U.S. Cl. CPC G01R 29/18

(57) ABSTRACT

A synchrophaser measurement method applied to a P Class Phasor Measurement Unit (PMU), and is based on the dynamic phasor mathematical model. The method includes providing a low pass digital filter for phasor factors and applying Discrete Fourier Transform, so that the spectrum leakage caused by the dynamic phasor inputs is eliminated, and the raw phasor measurements after the spectrum leakage being eliminated can be obtained. In addition, the dynamic phasor inputs are fitted by using the second order Taylor series and the linear relationship between the measurement errors causing the Discrete Fourier Transform averaging effect and the second order coefficients of the Taylor series is explored. The linear relationship is used to correct for the raw measurement errors under a dynamic condition, and the accurate dynamic phasor measurements can thus be obtained. This measurement method can measure phasor accurately and rapidly under both static and dynamic conditions.

### TECHNICAL FIELD

The field relates to phasor measurement technical field, especially involves a kind of synchrophasor measurement method applying to P class Phasor Measurement Unit (PMU).

### BACKGROUND

At present, the application of Phasor Measurement Unit (PMU) brings revolutionary reform for measuring technology of power system; except for providing synchrophasor, yet the advantage with high precision and high speed uploading frequency make PMU application widely as phasor data source in the dynamic security monitoring. The standard of IEEE C37.118.1 requests that P class PMU can trace power system dynamic response process rapidly and accurately; there is no request for smoothing and phasor antialiasing. Therefore, the phasor measuring precision and measuring speed is crucial especially under the dynamic condition. The inaccurate or slow response speed of measuring phasor may lead to incorrect control decisions, even expanding the breakdown.

The Discrete Fourier Transform (DFT) is widely used for phasor estimation in PMUs due to its low computational requirements, and also because it can extract the nominal frequency component from a waveform that is often corrupted with other harmonics. However, the DFT is based on the assumption that the parameters of the signal do not change, and the frequency stays as a nominal value within a time window. Nevertheless, during the dynamic response process of power system, this assumption is invalid and all the parameters change with time. Therefore, two measurement problems are introduced by deficiencies in the DFT. First, spectrum leakage occurs not only due to the frequency deviation, but also due to modulation of the inputs. Second, the static phasor model results in the averaging effect of the DFT, which introduces significant errors under dynamic conditions.

With the release and the gradual improvement of the PMU standards of IEEE and China, the PMU measurement precision under dynamic condition is valued by more and more research institutions; many new technologies are applied in the measurement method. For example, some literature propose simulating three-phase phasor by the method of translation time window to eliminate the spectrum leakage of DFT under the condition of frequency deviation. But this method is only suitable for static signal input; and the problem of spectrum leakage which is generated by dynamic signal inputs is not solved. So there is not one estimation algorithm which is based on dynamic phasor model in the existing technical solution. In addition, the problems of spectrum leakage and average effect, which are generated by dynamic signal inputs are not solved.

### SUMMARY OF THE INVENTION

One purpose of the invention is to provide a synchrophasor measurement method applying to P class Phasor Measurement Unit (PMU). This measurement method can measure phasor accurately and rapidly under both static and dynamic conditions. The precision of the method not only meets the requirements in relevant standards, but also is an order of magnitude higher than the requirements of the standards.

A synchrophasor measurement method applying to P class Phasor Measurement Unit (PMU), said measurement method is based on the dynamic phasor mathematic model, and the low pass digital filter for phasor factors is designed, and combined with DFT. Such combination eliminates the spectrum leakage caused by the dynamic phasor inputs, and the initial phasor measurements after the spectrum leakage being eliminated can be obtained.

The dynamic phasor is fitted by using the second order Taylor series. The linear relationship between the measurement errors caused by the DFT averaging effect and the second order coefficients of the Taylor series are explored. Then, the linear relationship is used to compensate for the raw measurement errors under a dynamic condition. Finally, the accurate dynamic phasor measurements can be obtained.

The linear relationship between the measurement errors which caused the DFT averaging effect and the second order coefficients of the Taylor series is explored, and, the linear relationship is used to compensate the raw measurement errors under a dynamic condition, and, the accurate dynamic phasor measurements can be obtained, comprises:

the coefficients of the second order Taylor series of the dynamic phasor input being calculated by least square method; and the raw frequency, the ROCOF (the rate of change of frequency) and their coefficients of the second order Taylor series are obtained, wherein all parameters of the dynamic phasor input are recomputed according to the coefficients of the second order Taylor series; and conducting dynamic compensation for the parameters of the raw phasor measurements, and static compensation for the amplitude; and the accurate dynamic phasor measurements are obtained by the dynamic calibration; and

the raw dynamic phasor parameters are calibrated; and, the static compensation to the amplitude of raw dynamic phasor; the accurate dynamic phasor measurements are obtained by the dynamic calibration.

After obtaining the accurate dynamic phasor measurements, the measurement method also includes:

a second low pass digital filter is introduced to eliminate the effect of the harmonic and the white noise to get phasor measurements with higher precision;

the cut-off frequency of the low pass digital filter combined with Discrete Fourier Transform (DFT) is 2.5 Hz; the time window is two rated periods of the dynamic input signal; the calculated frequency of the raw phasor is 400 Hz.

the cut-off frequency of the second low pass digital filter is 2.5 Hz; the time window is 27.5 ms.

From the above technical solution that the invention provides, it can be seen that this measurement method can obtain phasor measurements accurately and rapidly under both static and dynamic conditions. In addition, the precision of the measurement method can achieve an accuracy of one order of magnitude higher than the requirements in the standard.

### DESCRIPTION OF THE DRAWINGS

To clearly describe this technical solution of this embodiment of invention, there will be a simple introduction for the needed figures in the description of the project case. Obviously, the following described figures are only some project cases of this invention. For the general technical staff in this field, they can also get other figures according to them under without paying any creative work.

FIG. 1 is a flow diagram of the synchrophasor measurement method applying to P class Phasor Measurement Unit (PMU) enumerated by the embodiment of the invention;

FIG. 2 shows a relationship of amplitude measuring errors and frequencies enumerated by the embodiment of the invention;

FIG. 3 shows a maximum TVE (total vector error) under different fundamental frequencies in the simulation of the frequency scan test enumerated by the embodiment of the invention;

FIG. 4 shows a maximum frequency and rate of change of frequency (ROCOF) errors under different fundamental frequencies in the simulation of the frequency scan test enumerated by the embodiment of the invention;

FIG. 5 shows a maximum TVE (total vector error) under different modulation frequencies and in the simulation of the modulation test enumerated by the embodiment of the invention;

FIG. 6 shows maximum frequency errors under different modulation frequencies in the simulation of the modulation test enumerated the embodiment of the invention;

FIG. 7 shows maximum ROCOF errors under different modulation frequencies in the simulation of the modulation test enumerated the embodiment of the invention.

### DETAILED DESCRIPTION OF EMBODIMENTS OF THE INVENTION

The examples and the referenced drawings in this detailed description are merely exemplary, and should not be used to limit the scope of the claims in any claim construction or interpretation.

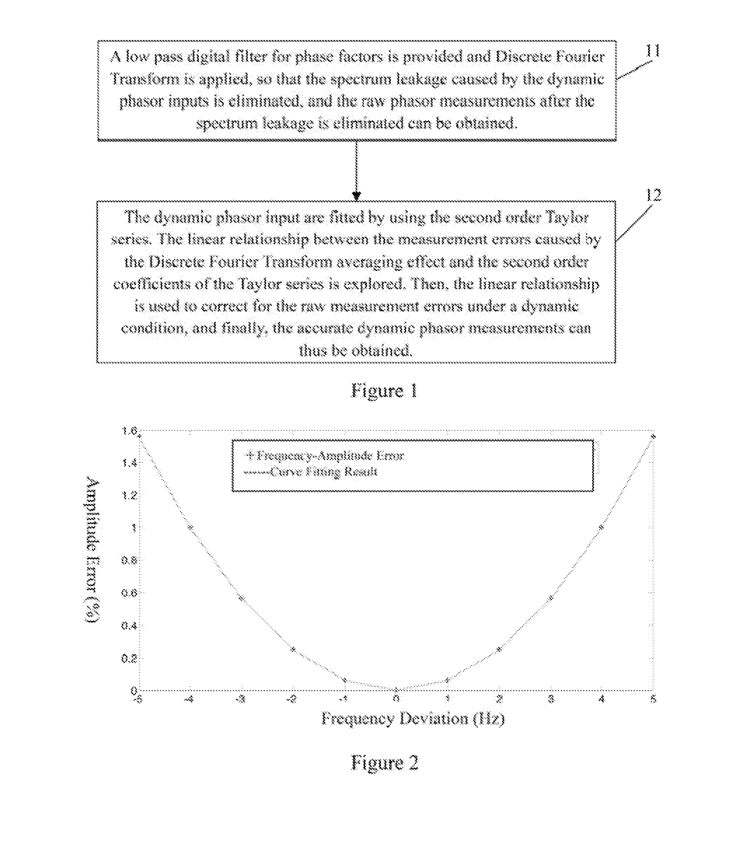

The embodiment of the invention is further described in detail with the figures. FIG. 1 is a flow diagram of the synchrophasor measurement method applying to P class Phasor Measurement Unit (PMU) enumerated by an embodiment of the invention. The method comprises:

Step 11: Step 11 comprises providing a low pass digital filter for phasor factors and applying Discrete Fourier Transform, so that the spectrum leakage caused by the dynamic phasor inputs is eliminated, and the raw phasor measurements after the spectrum leakage is eliminated can be obtained.

In this step, the mathematic model of the dynamic phasor is stated. For the implementation of the calculation, the mathematic model of the dynamic phasor based on the second order Taylor series is utilized. In this model, all parameters of the phasor including the amplitude, the phase angle, the frequency and the ROCOF change along with the time in the calculated time window.

For example, first, the dynamic fundamental frequency signal is now expressed as:

$$\begin{matrix}x ( t ) = \sqrt{2} {X}_{m} ( t ) cos ( {\int }_{0}^{t} 2 π f ( t ) d t + {ϕ}_{0} ) \\ = \sqrt{2} {X}_{m} ( t ) cos ( {\int }_{0}^{t} 2 π ( {f}_{0} + Δ f ( t ) ) d t + {ϕ}_{0} ) \\ = \sqrt{2} {X}_{m} ( t ) cos ( 2 π {f}_{0} t + ( 2 π {\int }_{0}^{t} Δ f ( t ) d t + {ϕ}_{0} ) )\end{matrix} \qquad ( 1 )$$

where x(t) is the instant value of the signal, Xₘ(t) is amplitude, f(t) is signal frequency, φ₀ is the raw phase angle, f₀ is the nominal frequency, Δf(t) is the frequency deviation. The amplitude and the frequency of the signal are a function of time.

The foregoing formula (1) is rewritten as follows:

$$\begin{matrix}x ( t ) = Re \{ {X}_{m} {e}^{j ( 2 π {f}_{0} Δ t ( {\int }_{0}^{t} Δ f ( t ) d t + {ϕ}_{0} ) )} \} \\ = Re \{ [ {e}^{j ( 2 π {f}_{0} t )} ] {X}_{m} {e}^{j ( 2 π {\int }_{0}^{t} Δ f ( t ) d t + {ϕ}_{0} )} \}\end{matrix} \qquad ( 2 )$$

where Rₑ is the real part of the formula. Then it is customary to neglect e^{j(2πƒof)} in the expression above, with the understanding that the reference coordinate system synchronously rotates with the angular frequency of 2πf₀. Then formula (1) is represented by \dot{x}, a mathematic model formula of dynamic phasor:

$$\begin{matrix}x ( t ) \dot{X} = {X}_{m} ( t ) {e}^{j ( 2 π {\int }_{0}^{t} Δ f ( t ) d t + {ϕ}_{0} )} \\ = {X}_{m} ( t ) ∠ ( 2 π {\int }_{0}^{t} Δ f ( t ) d t + {ϕ}_{0} ) \\ = {X}_{m} ( t ) [ cos ( 2 π {\int }_{0}^{t} Δ f ( t ) d t + {ϕ}_{0} ) + \\ j sin ( 2 π {\int }_{0}^{t} Δ f ( t ) d t + {ϕ}_{0} ] )\end{matrix} \qquad ( 3 )$$

The rate of change of frequency (ROCOF) is given by

ROCOF=d/dt[f(t)]=Δf′(t) (4)

Consequently, all the parameters of the dynamic phasor are a function of time. In order to approximate the dynamic input within one time window, the second-order Taylor series is applied for all the parameters of the phasor to imitate the non-linear changing waveform, as shown in the following formulas (5-8),

Xₘ(t)=m₂t²+m₂t+m₀ (5)

φ(t)=n₂t²+nₗt+n₀ (6)

f(t)=p₂t²+p₂t+p₀ (7)

ROCOF(t)=qₗt²+q₁l+q₀ (8)

where m₂=d²Xₘ(t)/dt²|ₜ₌₀, m₁=dXₘ(t)/dt|ₜ₌₀, m₀=Xₘ(0); n₂=d²φ(t)/dt²|ₜ₌₀, n₁=dφ(t)/dt|ₜ₌₀, n₀=φ(0); p₂=d²f(t)/dt²|ₜ₌₀, p₂=df(t)/dt|ₜ₌₀, p₀=f(0); q₂=d²ROCOF(t)/dt²|ₜ₌₀, q₁=d ROCOF(t)/dt|ₜ₌₀, q₀=ROCOF(0)

Then, based on the dynamic phasor mathematic model, the phenomenon of spectrum leakage caused by DFT under the dynamic phasor input condition and its impact on phasor measurements are analyzed. The DFT with the low pass digital filter is proposed to eliminate the spectrum leakage and get the raw phasor (\hat{x}ₘ and \hat{φ}). The cut-off frequency of the low pass digital filter combined with DFT is 2.5 Hz; the time window is 2 rated periods of the dynamic phasor input signal; the calculation frequency of the raw phasor is 400 Hz.

For example, first, the formula of traditional DFT algorithm in current technology is:

$$\dot{X} = \frac{\sqrt{2}}{N} {\sum }_{k = 0}^{N - 1} x ( k ) {e}^{- jk 2 π {f}_{0} Δ t} \qquad ( 9 )$$

Where \dot{x} is the measured phasor, N is the sample number, x(k) is the kth sample value, f₀ is the rated frequency, and Δt is the sample interval.

It can be concluded that the calculation process of the DFT is to acquire the phasor measurement by averaging the products of the signal samples and orthogonal coefficients in a time window. Then, supposing γ is

γ={γₖ|γₖ=x(k)e^{jk2πƒ0Δ}},k=0,1, . . . ,N−1 (10)

Extracting the real part and imaginary part of γ is as follows

Cₓ=Re(γ)=XC (11)

Sₓ=Im(γ)=XS (12)

where X={diag[x(k); n=0, 1, . . . , N−1]}, C^{T}=[cos [2πf₀(0)Δt], cos [2πf₀(1)Δt], . . . , cos [2πf₀(N−1)Δt]], S^{T}=[sin [2πf₀(0)Δt], sin [2πf₀(1)Δt], . . . , sin [2πf₀(N−1)Δt]]. Then, Cₓ and Sₓ are referred to the phasor factors whose properties are fundamental to the measurement characteristic of DFT. Then formula (1) can be rewritten with phasor factors, which is as follows:

$$\dot{X} = \frac{\sqrt{2}}{N} {\sum }_{k = 0}^{N - 1} {C}_{x} ( k ) - j {S}_{x} ( k ) . \qquad ( 13 )$$

If the input signal is static and with nominal frequency,

x(t)=\sqrt{2}Xₘcos(2πf₀t+φ₀) (14)

Then the Cₓ and Sₓ are

$$\begin{matrix}\begin{matrix}{C}_{x} ( k ) = x ( k ) cos ( 2 π {f}_{0} k Δ t ) \\ = \frac{\sqrt{2}}{2} {X}_{m} cos ( 4 π {kf}_{0} Δ t + {ϕ}_{0} ) + \frac{\sqrt{2}}{2} {X}_{m} cos ( {ϕ}_{0} )\end{matrix} & ( 15 ) \\ \begin{matrix}{S}_{x} ( k ) = x ( k ) sin ( 2 {π}_{0} k Δ t ) \\ = \frac{\sqrt{2}}{2} {X}_{m} sin ( 4 k π {f}_{0} Δ t + {ϕ}_{0} ) - \frac{\sqrt{2}}{2} {X}_{m} {sin ( {ϕ}_{0} )}^{*}\end{matrix} & ( 16 )\end{matrix}$$

As shown in the foregoing formulas (15) and (16), when k is increased, the phasor factors are composed of a 2f₀ component and a direct current component. By averaging the phasor factors in one cycle of the signal, the 2f₀ component can be eliminated, and then the real phasor can be obtained, as shown in the following formula (17). This is one cycle DFT algorithm.

$$\dot{X} = \frac{\sqrt{2}}{2} {X}_{m} cos ( {ϕ}_{0} ) + j \frac{\sqrt{2}}{2} {X}_{m} sin ( {ϕ}_{0} ) = {X}_{m} {∠ϕ}_{0} \qquad ( 17 )$$

The DFT algorithm is widely used because of its capability of excluding harmonics and extracting the fundamental wave. However, if the frequency drifts from the nominal value, spectrum leakage will occur. In particular, when the frequency varies with time, it is difficult to remove the spectrum leakage. Also, when inputting the dynamic signal, spectrum leakage will also occur.

First, use the formula (1) as the input signal, then Cₓ and Sₓ will be

$$\begin{matrix}\begin{matrix}{C}_{x} ( k ) = x ( k ) cos ( {ω}_{0} k Δ t ) \\ = \frac{\sqrt{2}}{2} {X}_{m} ( k Δ t ) cos [ 2 π {\int }_{0}^{k Δ t} f ( t ) d t + 2 π {kf}_{0} Δ t + {ϕ}_{0} ] + \\ \frac{\sqrt{2}}{2} {X}_{m} ( k Δ t ) cos ( 2 π {\int }_{0}^{k Δ t} Δ f ( t ) d t + {ϕ}_{0} ) \\ = {C}_{1} + {C}_{2}\end{matrix} & ( 18 ) \\ \begin{matrix}{S}_{x} ( k ) = x ( k ) sin ( {ω}_{0} k Δ t ) \\ = \frac{\sqrt{2}}{2} {X}_{m} ( k Δ t ) sin [ 2 π {\int }_{0}^{k Δ t} f ( t ) d t + 2 π {kf}_{0} Δ t + {ϕ}_{0} ] - \\ \frac{\sqrt{2}}{2} {X}_{m} ( k Δ t ) sin ( 2 π {\int }_{0}^{k Δ t} Δ f ( t ) d t + {ϕ}_{0} ) \\ = {S}_{1} + {S}_{2} .\end{matrix} & ( 19 )\end{matrix}$$

The real phasor should be like the formula (3), which is composed of C₂ and S₂ of formula (18) and formula (19). However, C₁ and S₁ cannot be eliminated, since their frequencies are no longer the integer multiple of f₀. Therefore, spectrum leakage will occur.

As shown in the mentioned formulas (18) and (19), the frequencies of the frequency components that result in spectral leakage are all around 2f₀, while the frequencies of the frequency components composing the real phasor are relatively low. According to the requirements of P-class PMU in IEEE C37.118.1 standard, Δf and f₁ are all less than 2 Hz, a low pass filter can be implemented to retain low-frequency components while filtering high-frequency components in phasor factors. And this is why the embodiment of the invention utilizes improved DFT algorithm with the low-pass digital filter, in the purpose of eliminating spectrum leakage and obtain the initial phasor (\tilde{X}ₘ′and \tilde{φ}^{r}). The formula is as follows:

$$\tilde{\dot{X}} = \frac{\sqrt{2}}{s} {\sum }_{k = \frac{N - 1}{2}}^{\frac{N - 1}{2}} x ( k + \frac{N - 1}{2} ) h ( k + \frac{N - 1}{2} ) {e}^{- j k π {f}_{0} Δ t}$$

where \dot{\tilde{X}} is the calculated phasor,

$$h ( k + \frac{N - 1}{2} )$$

is the low-pass filter coefficients, and

$$s = {\sum }_{k = \frac{N - 1}{2}}^{\frac{N - 1}{2}} h ( k + \frac{N - 1}{2} ) .$$

It should be noticed that k starts from −(N−1)/2, because the time tag position is set in the middle of the time window.

Formula (24) is rewritten with the phasor factor:

$$\begin{matrix}\tilde{\dot{X}} = \frac{\sqrt{2}}{s} {\sum }_{k = \frac{N - 1}{2}}^{\frac{N - 1}{2}} h ( k + \frac{N - 1}{2} ) [ {C}_{x} ( k ) - j {S}_{x} ( k ) ] \\ = \frac{\sqrt{2}}{s} {\sum }_{k = \frac{N - 1}{2}}^{\frac{N - 1}{2}} {\{ \begin{matrix}\frac{\sqrt{2}}{2} {X}_{m} ( k Δ t ) h ( k + \frac{N - 1}{2} ) \cdot \\ [ \begin{matrix}cos ( 2 π {\int }_{- \frac{N - 1}{2} Δ t}^{k Δ t} Δ f ( t ) d t + {ϕ}_{0} ) + \\ j sin ( 2 π {\int }_{- \frac{N - 1}{2} Δ f}^{k Δ t} Δ f ( t ) d t + {ϕ}_{0} )\end{matrix} ]\end{matrix} \}}^{*} \\ = \frac{1}{s} {\sum }_{k = - \frac{N - 1}{2}}^{\frac{N - 1}{2}} {X}_{m} ( k Δ t ) h ( k + \frac{N - 1}{2} ) {e}^{j 2 π {\int }_{- \frac{N - 1}{2}}^{k Δ t} Δ f ( t ) d t} {e}^{{jϕ}_{0}}\end{matrix} \qquad ( 25 )$$

It can be seen that although the spectral leakage is eliminated, the amplitude of \dot{\tilde{X}} depends on Xₘ(t), Δf(t), and the filter coefficients. Only when Xₘ(t) is constant and Δf(t)=0, the accurate phasor which is \dot{\tilde{X}}=Xₘe¹⁵⁰ can be obtained. Otherwise an error of the amplitude measurement exists. But, the filter coefficients are treated as fixed for an implemented algorithm. The amplitude calculated error is only related to Δf(t). The function between them can be assumed and approximated to a quadratic function by the curve fitting of the simulation data, what shown in FIG. 2, where

$$Magnitude Error = \frac{\vert \vert \dot{X} \vert - \vert \tilde{\dot{X}} \vert \vert}{\vert \dot{X} \vert} \times 100 \% .$$

Step 12: Step 12 comprises fitting the dynamic phasor inputs by using the second order Taylor series, the linear relationship between the measurement errors caused by the Discrete Fourier Transform averaging effect and the second order coefficients of the Taylor series is explored, and, the linear relationship being used to correct for the raw measurement errors under a dynamic condition, and, the accurate dynamic phasor measurements can thus be obtained.

In this step, first, the dynamic phasor input is fitted by using the second order Taylor series. The linear relationship between the measurement errors caused by the DFT averaging effect and the second order coefficients of the Taylor series is explored. Then, the linear relationship is used to calibrate the raw measurement errors. Finally, the accurate dynamic phasor measurements can be gotten.

Specifically, first, the coefficients of the second order Taylor series of the dynamic phasor input are calculated by least square method; and the raw frequency, the ROCOF (ƒ̅^{r}and ROCO\tilde{F}^{r}) and their coefficients of the second order Taylor series are obtained. All parameters of the dynamic phasor are recomputed according to the coefficients of the second order Taylor series;

Second, the raw dynamic phasor parameters are calibrated to obtain φ̅ₗ^{r}, ƒ̅ₗ^{r} and ROCO\tilde{F}ₗ^{r};

Then, the static compensation to the amplitude of raw dynamic phasor is made to get \tilde{X}ₘₗ ^{r} according to \tilde{ƒ}ₗ^{r}; and the dynamic measurement phasor \tilde{X}ₘ₂^{r} is obtained by the dynamic calibration.

For example, by implementation of the DFT with a low pass filter as stated in step 11, the raw phasor that is immune to the spectrum leakage is computed. However, because of the assumption that the phasor is at steady state, the raw phasor measurement is still not accurate enough with dynamic inputs, which cannot meet the requirement of the standard.

During power system oscillations, the amplitude, phase angle, frequency and ROCOF change non-linearly.

Substitute Xₘ(t) in formula (25) with the formula (5), and suppose the Δf(t)=0 for simplification of the derivation process, the formula (25) can be rewritten as:

$$\begin{matrix}\tilde{\dot{X}} = \frac{1}{s} {\sum }_{k = \frac{N - 1}{2}}^{\frac{N - 1}{2}} [ {{m}_{2} ( k Δ t )}^{2} + {m}_{1} ( k Δ t ) + {m}_{0} ] h ( k + \frac{N - 1}{2} ) {e}^{j {ϕ}_{0}} \\ = \frac{1}{s} {e}^{j {ϕ}_{0}} \{ {m}_{2} Δ {t}^{2} {K}_{2} H + {m}_{1} Δ t {K}_{1} H + {m}_{0} EH \}\end{matrix}$$

$$where$$

$${K}_{2} = [ {( - \frac{N - 1}{2} )}^{2} , {( - \frac{N - 1}{2} + 1 )}^{2} , … , 0 , … , {( \frac{N - 1}{2} )}^{2} ] , \\ {K}_{1} = {[ - \frac{N - 1}{2} )}^{2} , - \frac{N - 1}{2} + {1}^{2} , … , 0 , … , ( \frac{N - 1}{2} ] , \\ E = [ t , 1 … t ] , \\ H = {[ h ( 0 ) , h ( 1 ) , … , h ( N - 1 ) ]}^{T} .$$

Since the coefficients of the filter is symmetrical, so H can be expressed as

$$H = {[ h ( 0 ) , h ( 1 ) , … , h ( \frac{N - 1}{2} ) , … , h ( 1 ) , h ( 0 ) ]}^{T} .$$

### Therefore,

$$\begin{matrix}EH / s = \frac{h ( 0 ) + h ( 1 ) + … + h ( N - 1 )}{h ( 0 ) + h ( 1 ) + … + h ( N - 1 )} = 1 & ( 27 ) \\ {K}_{t} H / s = \frac{h ( 0 ) ( - \frac{N - 1}{2} ) + … h ( \frac{N - 1}{2} ) ( 0 ) + … + h ( 0 ) ( \frac{N - 1}{2} )}{h ( 0 ) + h ( 1 ) + … + h ( N - 1 )} = 0 & ( 28 ) \\ \begin{matrix}{K}_{2} H / s = \frac{\begin{matrix}h ( 0 ) {( - \frac{N - 1}{2} )}^{2} + \\ h ( 1 ) {( - \frac{N - 1}{2} + 1 )}^{2} + … + h ( N + 1 ) {( \frac{N - 1}{2} )}^{2}\end{matrix}}{h ( 0 ) + h ( 1 ) + … + h ( N - 1 )} \\ = {\tilde{K}}_{2}\end{matrix} & ( 29 )\end{matrix}$$

where \tilde{K}₂ is the weighted average of K₂. Substitute the relative variables in formula (26) with formula (27), (28), (29),

\dot{\tilde{X}}=(m₂Δt²\tilde{K}₂+m₀)e^{ƒro}0 (30)

Since the time tag is set in the middle of the time window, the real phasor is \dot{X}=[m₂(0)²+m₁(0)+m₀]e^{jpo}=m₀e^{jpo}. Therefore, the phasor amplitude, measurement error is

eₘ=|\dot{\tilde{X}}|−|\dot{X}|=m₂Δt²\tilde{K}₃=αm₂ (31)

where eₘ is the amplitude measurement error, α=Δt²\tilde{K}₂. For an implemented algorithm in a device, the sample interval, the coefficients of the filter are fixed, so Δt and \tilde{K}₂ are constant. Consequently, the phasor amplitude measurement error has a linear relationship with m₂. In addition, the slope coefficient of the linear relationship is dependent on the low pass filter.

In order to compensate for the measurement error, m₂ needs to be calculated first. Supposing the phasor of “M” amplitude measurements calculated by formula (20) is given by

$$[ \begin{matrix}{\tilde{X}}_{m}^{0} \\ {\tilde{X}}_{m}^{1} \\ {\tilde{X}}_{m}^{2} \\ ⋮ \\ {\tilde{X}}_{m}^{M - 1}\end{matrix} ] = [ \begin{matrix}1 & 0 & 0 \\ 1 & Δ {t}_{c} & Δ {t}_{c}^{2} \\ 1 & 2 Δ {t}_{c} & {2}^{2} Δ {t}_{c}^{2} \\ ⋮ & ⋮ & ⋮ \\ 1 & ( M - 1 ) Δ {t}_{c} & {( M - 1 )}^{2} Δ {t}_{c}^{2}\end{matrix} ] [ \begin{matrix}{m}_{0} \\ {m}_{1} \\ {m}_{2}\end{matrix} ] . \qquad ( 32 )$$

where \tilde{X}ₘ is the rth phasor amplitude measurement, Δt_{c} is the phasor calculation interval. The above-mentioned formula can be written in matrix notation:

\tilde{X}ₘ=T_{c}Cₘ (33)

where T is the coefficient matrix. The unknown matrix Cₘ is calculated by the weighted least-squares (WLS) technique:

Cₘ=|T_{c}^{T}T_{c}|⁻¹T_{c}^{T}\tilde{X}ₘ. (34)

Again, since the time tag is set in the middle,

$${\tilde{X}}_{m}^{\frac{M - 1}{2}}$$

is recalculated to achieve the approximated curve:

$${\tilde{X}}_{m}^{\frac{M - 1}{2}} = {( \frac{M - 1}{2} Δ {t}_{c} )}^{2} {m}_{2} + \frac{M - 1}{2} Δ {t}_{c} {m}_{1} + {m}_{2}$$

Then the calculated m₂ is used to calibrate

$${\tilde{X}}_{m}^{\frac{M - 1}{2}} .$$

The compensated coefficient α can be determined by simulation experiments.

Similarly, n₂ can also be calculated by this method with the measurement phasor (\tilde{ψ}). Then the original frequency and ROCOF measurements are obtained by

$$\begin{matrix}\tilde{f} = {n}_{2} \frac{M - 1}{2} Δ {t}_{c} / π + {n}_{2} / 2 π & ( 36 ) \\ ROCO \tilde{F} = {n}_{2} / π & ( 37 )\end{matrix}$$

For the time changing of φ(t), f(t), and ROCOF(t), their measurement errors are also linearly related with the second-order coefficients of each of their Taylor expressions. These can be verified by the simulation results. In addition, in the specific realization process, this embodiment of the invention introduces a low pass digital filter in the traditional DFT to eliminate the spectrum leakage and the frequency aliasing phenomenon caused dynamic inputs. However, the low pass digital destroys the characteristic of traditional DFT which is being able to eliminate the integer harmonics. Therefore, the second low pass digital filter after getting the accurate dynamic phasor measurements is applied to get rid of the influence of harmonics and white noises. Then, phasor measurements with higher precision can be obtained, that is \tilde{X}ₘ₀, \tilde{φ}₂, \tilde{f}₂^{T} and ROCO\tilde{F}₂^{r}. N^{r} is the time window length of the second low pass digital filter. Since P class PMU requires faster corresponding speed for step signals, the order of the second digital filter is lower. However, it has still enough inhibitory effect for harmonic interferences.

In the specific realization, the cut-off frequency of the second low pass digital filter is 2.5 Hz. To ensure the fast dynamic responding speed, the time window is set as 27.5 ms.

Specific embodiments are applied to conduct simulation test for the aforesaid measurement method. The following details are described:

The IEEE C37.118.1 standard has specified the maximum errors in phasor measurement and the static and dynamic tests to imitate the static and dynamic processes of the power system in a complete and full manner. The proposed synchrophasor measurement method of the embodiment of the invention has been subject to the simulation test under the frequency deviation, harmonic contamination, oscillation, out of step, and fault. A comparison of the error limits of the standard is outlined to demonstrate the merit of the proposed method. For implementing the algorithm, the nominal frequency is 50 Hz, the reporting rate is 50 Hz, and the sample rate is 1200 Hz. N=48, M=7, N′=10 The matrix Cₘ in formula (34) can be calculated in advance, and the look-up table method can be used when the phasor is estimated. The overall computation load for the phasor, the frequency, and the ROCOF is approximately 296 multiplications and 237 summations.

1) Frequency Scan Test

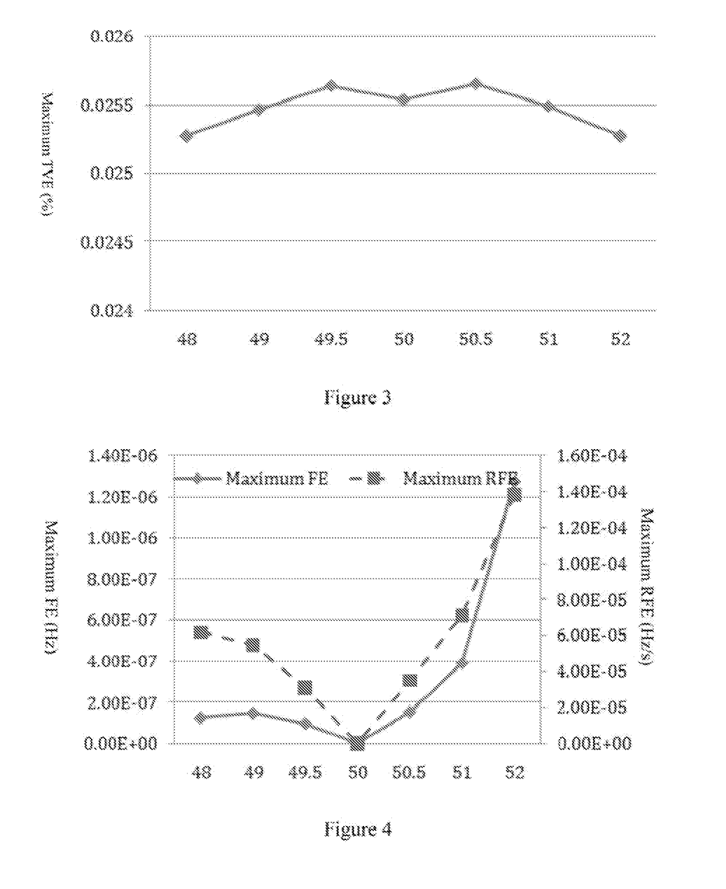

Different power system operation modes may cause the frequency to drift from its nominal value. In addition, faults can lead to major frequency excursions. In this section, the measurement accuracy of the proposed algorithm exposed to the signals with the frequency excursion is investigated. The frequency changing range of the input signal is from 48 Hz to 52 Hz, and remains steady during each state. In the frequency scan test of IEEE C37.118.1a, the maximum total vector error (TVE) is limited within 1%, the maximum frequency error (FE) is 0.005 Hz, and the maximum ROCOF error (RFE) is 0.1 Hz/s. The corresponding measurements are shown in FIG. 3 and FIG. 4. FIG. 3 shows a maximum WE under different fundamental frequencies in the simulation of the frequency scan test enumerated by the embodiment of the invention; FIG. 4 shows maximum frequency and ROCOF errors under different fundamental frequencies in the simulation of the frequency scan test enumerated by the embodiment of the invention. It can be observed that the proposed algorithm achieves much better accuracy than the requirements set forth in IEEE C37.118.1a.
2) Influence of Harmonic Test

In this section, power system signal of 1% of the 2^{nd}, 3^{rd}, 8^{th} and 13^{th} harmonic under 50 Hz are applied to investigate the harmonic immune capability of the proposed algorithm. The error limits in the standard (std.) are outlined in Table I as well.

The measurement results for each harmonic contamination case are outlined in Table I. It can be noted that the errors for the even order harmonics are bigger than that for the odd order ones. However, the errors are well below the required limits, which demonstrate that the proposed method is immune to harmonic contamination.

TABLE I
Error Statistics under the Influence of Harmonics

| Fundamental | | Maximum | Maximum | Maximum |
|---|---|---|---|---|
| Frequency | | TVE (%) | FE (Hz) | RFE (Hz/s) |
| (Hz) | Harmonic | Std.: 1 | Std.: 0.005 | Std.: 0.1 |
| 50 | 2nd | 0.005676 | 0.00016608 | 0.070205 |
| | 3rd | 0.025545 | 4.4764e−013 | 5.1082e−011 |
| | 8th | 0.0052927 | 8.2816e−005 | 0.035021 |
| | 13th | 0.025525 | 4.4764e−013 | 5.1097e−011 |

3) Modulation Test

The modulation test is applied to reflect the variations in amplitude and phase angle of the voltage waveforms when the electric power system oscillates. In general, at network node, the amplitude and phase angle of positive sequence voltages shall oscillate simultaneously, with the two modulations being in phase opposition. During the test, the amplitude and the phase angle of the signal change as a sinusoidal function. The error would be at a maximum where the non-linear extents are the most severe (the oscillation peak or valley, etc.).

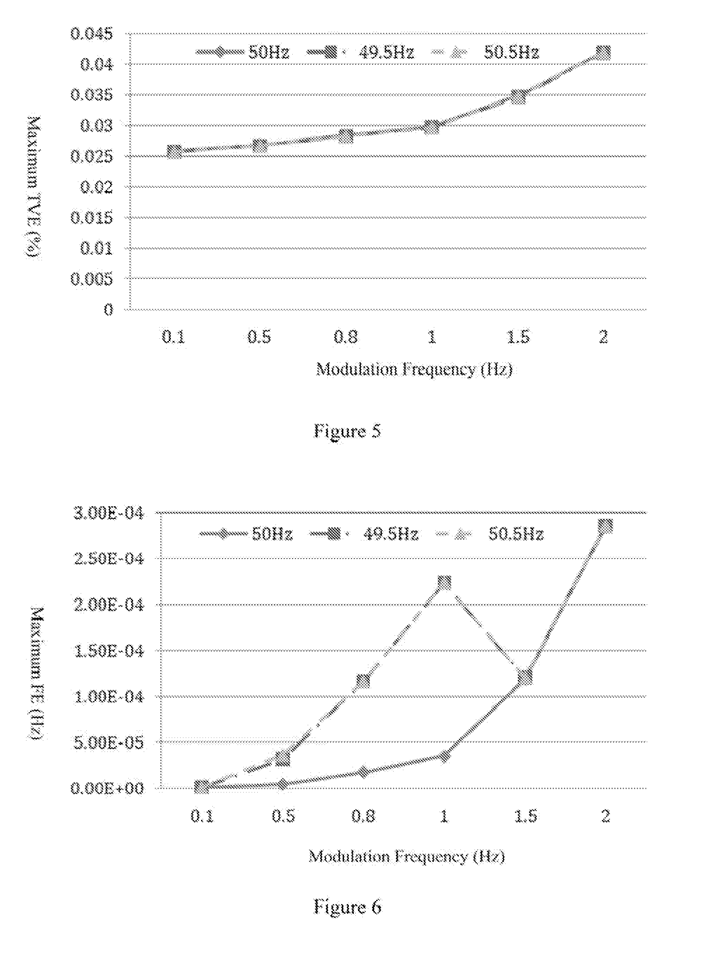

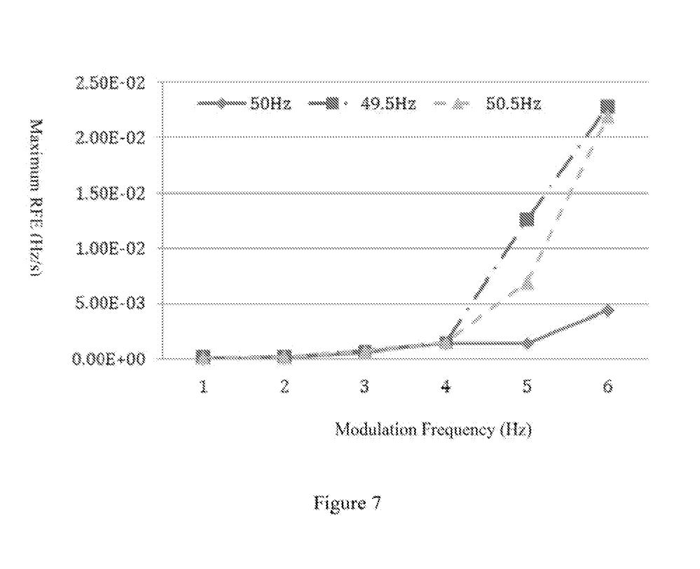

In this test, consider that the amplitude modulation depth is 10%, the phase angle modulation depth is 0.1 rad, and the modulation frequency varies from 0.1 Hz to 2 Hz. In the modulation test of IEEE C37.118.1a, the maximum TVE is limited within 3%, and the maximum frequency error (FE) is 3 Hz. The measurement errors are shown in FIG. 5, FIG. 6, and FIG. 7. FIG. 5 shows the maximum TVE under different modulation frequency in the simulation of modulation test, as enumerated in an embodiment of the invention; FIG. 6 shows the maximum frequency error under different modulation frequency in the simulation of modulation test, as enumerated in the embodiment of the invention; FIG. 7 shows the maximum ROCOF error under different modulation frequency in the simulation of modulation test, as enumerated in the embodiment of the invention; It can be seen from FIGS. 5-7 that all the measurements errors continuously increase as the modulation frequency grows, because the signal changes faster and faster within one time window. Nevertheless, the proposed algorithm exhibits a precisely dynamic tracking ability compared to the error limits in IEEE C37.118.1a.

4) Frequency Ramp Test

The frequency ramp test aims to imitate a power system out of step, which is different from the frequency scan test where the fundamental frequency of the signal is changed from 48 Hz to 52 Hz at a rate of 1 Hz/s. It can be seen from the test that the measurement method proposed by the invention can measure phasor, frequency and rate of change of frequency under continuously changing frequency accurately, as shown in Table II.

TABLE II
Error Statistics under the Ramp of Frequency Test

| | Maximum | Maximum | Maximum RFE |
|---|---|---|---|
| Frequency | TVE (%) | FE (Hz) | (Hz/s) |
| Range | Std.: 1 | Std.: 0.01 | Std.: 0.1 |
| 48 Hz~52 Hz | 0.0321 | 4.72e−006 | 1.32e−004 |

5) Step Test

The sudden changes in the amplitude and phase angle of the voltage and current waveforms may occur when there are faults or switching operations in power systems. For the P class PMUs, the response speed is crucial for the dynamic security monitoring of the power system.

In this test, a input signal arises a 10% amplitude step and a 10° phase angle step. The response times are shown in Table III. One can see that the response time of the phasor can satisfy the standards requirements.

TABLE III
Response Times under the Step Test

| | | | Frequency |
|---|---|---|---|
| | | | Change |
| | Phasor | Frequency | Rate |
| Response Time (ms) | Std.: 34 | Std.: 70 | Std.: 80 |
| 10% Amplitude Step-leap | 23.7 | 42.5 | 67.5 |
| 10° Phase Angle Step-leap | 22.1 | 69 | 78 |

To sum up, the measurement method of the embodiment of the invention can compute the phasor measurements accurately during conditions of the frequency deviation, the power oscillation and the out of step. In addition, the method has the fast response speed and the capability of immune to integer harmonic and non-integer harmonics.

The scope of the claims should not be limited by the preferred embodiments and examples described herein, but should be given the broadest interpretation consistent with the written description as a whole.

1. A synchrophaser measurement method applied to a P Class Phasor Measurement Unit (PMU), the method being based on the dynamic phasor mathematical model and comprising:
providing a low pass digital filter for phasor factors and applying Discrete Fourier Transform, so that the spectrum leakage caused by the dynamic phasor inputs is eliminated, and the raw phasor measurements after the spectrum leakage is eliminated can be obtained; and
fitting the dynamic phasor inputs by using the second order Taylor series, the linear relationship between the measurement errors caused by the Discrete Fourier Transform averaging effect and the second order coefficients of the Taylor series is explored, and, the linear relationship is used to correct for the raw measurement errors under a dynamic condition, and, the accurate dynamic phasor measurements can thus be obtained.

2. The method of claim 1, further comprising:
calculating the coefficients of the second order Taylor series of the dynamic phasor input by the least square method; and
obtaining the raw frequency, rate of change of frequency, and their coefficients of the second order Taylor series;
recomputing all parameters of the dynamic phasor input according to the coefficients of the second order Taylor series;
correcting for the raw dynamic phasor parameters;
providing static compensation to the amplitude of raw dynamic phasor
whereby the accurate dynamic phasor measurements are obtained by a dynamic calibration.

3. The method of claim 1, wherein after obtaining accurate dynamic phasor measurements, the measurement method further comprises introducing a second low pass digital filter to decrease the effect of harmonics and white noise and so as to obtain phasor measurements with higher precision.

4. The method of claim 1, wherein:
the cut-off frequency of the low pass digital filter combined with Discrete Fourier Transform is 2.5 Hz, the time window length is two rated periods of the dynamic input signal, and the calculation frequency of the raw phasor is 400 Hz.

5. The method of claim 3, wherein the cut-off frequency of the second low pass digital filter is 2.5 Hz and the time window is 27.5 ms.
